(19) United States
(12) Patent Application Publication
(10) Pub. No.: US 2025/0373222 A1
(43) Pub. Date: Dec. 4, 2025

(54) BULK ACOUSTIC WAVE DEVICE INCLUDING DIELECTRIC LAYER FOR FRAME MODE SUPPRESSION

(71) Applicant: Skyworks Global Pte. Ltd., Singapore (SG)

(72) Inventors: Yanbo He, Irvine, CA (US); Wan Wan, Irvine, CA (US); Kwang Jae Shin, Yongin (KR); Zongliang Cao, Irvine, CA (US)

(21) Appl. No.: 19/211,911

(22) Filed: May 19, 2025

Related U.S. Application Data
(60) Provisional application No. 63/653,143, filed on May 29, 2024.
(60) Provisional application No. 63/653,103, filed on May 29, 2024.
(60) Provisional application No. 63/653,141, filed on May 29, 2024.
(60) Provisional application No. 63/653,158, filed on May 29, 2024.

(51) Int. Cl. H03H 9/02; H03H 9/17

(52) U.S. Cl. CPC H03H 9/02086; H03H 9/173; H03H 9/176

(57) ABSTRACT

A bulk acoustic wave device is disclosed. The bulk acoustic wave device can include a piezoelectric layer positioned between first and second electrodes in a main acoustically active region and a frame region, a raised frame structure positioned in the frame region, and a raised frame structure positioned in the frame region. The piezoelectric layer has a first side facing the first electrode and a second side facing the second electrode. The raised frame structure has an inner end and an outer end. The dielectric layer is positioned between the first and second sides of the piezoelectric layer. The dielectric layer has an inner edge and an outer edge. A distance between the inner end of the raised frame structure and the main acoustically active region can be equal to or greater than a distance between the inner edge of the dielectric layer and the main acoustically active region.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/653,143, filed May 29, 2024, titled “BULK ACOUSTIC WAVE DEVICE INCLUDING DIELECTRIC LAYER FOR FRAME MODE SUPPRESSION,” U.S. Provisional Patent Application No. 63/653,103, filed May 29, 2024, titled “BULK ACOUSTIC WAVE DEVICE WITH DIELECTRIC LAYER POSITIONED IN PIEZOELECTRIC LAYER FOR FRAME MODE SUPPRESSION,” U.S. Provisional Patent Application No. 63/653,141, filed May 29, 2024, titled “DIELECTRIC LAYER AND REDUCED PIEZOELECTRIC REGION IN BULK ACOUSTIC WAVE DEVICE FOR FRAME MODE SUPPRESSION,” and U.S. Provisional Patent Application No. 63/653,158, filed May 29, 2024, titled “BULK ACOUSTIC WAVE DEVICE WITH AIRGAP FOR FRAME MODE SUPPRESSION,” are hereby incorporated by reference under 37 CFR 1.57 in their entirety.

### BACKGROUND

### Technical Field

The disclosed technology relates to acoustic wave devices. Embodiments of this disclosure relate to acoustic wave devices with a dielectric layer for frame mode suppression.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a raised frame structure positioned in the frame region, the raised frame structure having an inner end and an outer end, the inner end being closer to the main acoustically active region than the outer end; and a dielectric layer in the frame region, the dielectric layer positioned between the first side and the second side of the piezoelectric layer, the dielectric layer having an inner edge and an outer edge, a distance between the inner end of the raised frame structure and the main acoustically active region being equal to or greater than a distance between the inner edge of the dielectric layer and the main acoustically active region so as to suppress a frame mode associated with the raised frame structure.

In some embodiments, the techniques described herein relate to a bulk acoustic wave device further including a recessed frame structure in the frame region between the raised frame structure and the main acoustically active region.

In some embodiments, the techniques described herein relate to a bulk acoustic wave device wherein the dielectric layer at least partially overlaps the recessed frame structure.

In some embodiments, the techniques described herein relate to a bulk acoustic wave device wherein the inner end of the raised frame structure aligns with the inner edge of the dielectric layer.

In some embodiments, the techniques described herein relate to a bulk acoustic wave device wherein the dielectric layer includes a silicon oxide layer.

In some asp embodiments ects, the techniques described herein relate to a bulk acoustic wave device wherein the dielectric layer includes an airgap.

In some embodiments, the techniques described herein relate to a bulk acoustic wave device wherein the dielectric layer overlaps at least an entire portion of the raised frame structure.

In some embodiments, the techniques described herein relate to a bulk acoustic wave device further including a passivation layer over the second electrode.

In some embodiments, the techniques described herein relate to a bulk acoustic wave device wherein the dielectric layer has a lower side facing the first electrode, the lower side of the dielectric layer is spaced apart at least by 10% of a thickness of the piezoelectric layer from the first electrode.

In some embodiments, the techniques described herein relate to a multiplexer for filtering radio frequency signals, the multiplexer including: a first filter including the bulk acoustic wave device; and a second filter coupled to the first filter at a common node.

In some embodiments, the techniques described herein relate to a radio frequency module including: a filter including the bulk acoustic wave device; radio frequency circuitry; and a package structure enclosing the filter and the radio frequency circuitry.

In some embodiments, the techniques described herein relate to a radio frequency system including: an antenna; a filter including the bulk acoustic wave device; and an antenna switch configured to selectively electrically connect the antenna and a signal path that includes the filter.

In some aspects, the techniques described herein relate to a method of forming a bulk acoustic wave device having a main acoustically active region and a frame region, the method including: providing a first electrode; providing a first portion of a piezoelectric layer over the first electrode; providing a dielectric layer in the frame region over the first portion of the piezoelectric layer, the dielectric layer having an inner edge and an outer edge; providing a second portion of the piezoelectric layer over the first portion of the piezoelectric layer and the dielectric layer; providing a second electrode over the second portion of the piezoelectric layer; and providing a raised frame structure positioned in the frame region, the raised frame structure having an inner end and an outer end, the inner end being closer to the main acoustically active region than the outer end, a distance between the inner end of the raised frame structure and the main acoustically active region being equal to or greater than a distance between the inner edge of the dielectric layer and the main acoustically active region.

In some embodiments, the techniques described herein relate to a method further including providing a recessed frame structure in the frame region between the raised frame structure and the main acoustically active region.

In some embodiments, the techniques described herein relate to a method wherein the dielectric layer includes a silicon oxide layer.

In some embodiments, the techniques described herein relate to a method wherein the dielectric layer includes an airgap.

In some embodiments, the techniques described herein relate to a method wherein the dielectric layer overlaps at least an entire portion of the raised frame structure.

In some embodiments, the techniques described herein relate to a method further including a passivation layer over the second electrode.

In some embodiments, the techniques described herein relate to a method wherein the dielectric layer has a lower side facing the first electrode, the lower side of the dielectric layer is spaced apart at least by 10% of a thickness of the piezoelectric layer from the first electrode.

In some aspects, the techniques described herein relate to an acoustic wave filter for filtering a radio frequency signal, the acoustic wave filter including: a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a raised frame structure positioned in the frame region, the raised frame structure having an inner end and an outer end, the inner end being closer to the main acoustically active region than the outer end; and a dielectric layer in the frame region, the dielectric layer positioned between the first side and the second side of the piezoelectric layer, the dielectric layer having an inner edge and an outer edge, a distance between the inner end of the raised frame structure and the main acoustically active region being equal to or greater than a distance between the inner edge of the dielectric layer and the main acoustically active region; and a plurality of additional acoustic wave resonators, the bulk acoustic wave device and the plurality of additional acoustic wave resonators configured to filter the radio frequency signal.

In some aspects, the techniques described herein relate to a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a frame structure positioned in the frame region, the frame structure including a raised frame structure and a recessed frame structure between the raised frame structure and the main acoustically active region; and a dielectric layer in the frame region, the dielectric layer positioned between the first side and the second side of the piezoelectric layer, the dielectric layer having a lower side facing the first electrode, the lower side of the dielectric layer being spaced apart at least by 10% of a thickness of the piezoelectric layer from the first electrode.

In some embodiments, the techniques described herein relate to a bulk acoustic wave device wherein the dielectric layer has an upper side opposite the lower side, the upper side is spaced apart at least by 10% of the thickness of the piezoelectric layer from the second electrode.

In some embodiments, the techniques described herein relate to a bulk acoustic wave device wherein the dielectric layer is positioned within 20% to 80% of the thickness of the piezoelectric layer.

In some embodiments, the techniques described herein relate to a bulk acoustic wave device wherein the dielectric layer at least partially overlaps the recessed frame structure.

In some embodiments, the techniques described herein relate to a bulk acoustic wave device wherein the dielectric layer includes a silicon oxide layer.

In some embodiments, the techniques described herein relate to a bulk acoustic wave device wherein the dielectric layer includes an airgap.

In some embodiments, the techniques described herein relate to a bulk acoustic wave device wherein the dielectric layer overlaps at least an entire portion of the raised frame structure.

In some embodiments, the techniques described herein relate to a bulk acoustic wave device wherein the frame structure includes a raised frame structure having an inner end and an outer end, the inner end being closer to the main acoustically active region than the outer end.

In some embodiments, the techniques described herein relate to a bulk acoustic wave device wherein the dielectric layer has an inner edge and an outer edge, a distance between the inner edge of the dielectric layer and the main acoustically active region is no greater than 600 nanometers over a distance between the inner end of the raised frame structure and the main acoustically active region.

In some embodiments, the techniques described herein relate to a bulk acoustic wave device wherein the inner edge abuts the main acoustically active region.

In some embodiments, the techniques described herein relate to an acoustic wave filter for filtering a radio frequency signal, the acoustic wave filter including: the bulk acoustic wave device; and a plurality of additional acoustic wave resonators, the bulk acoustic wave device and the plurality of additional acoustic wave resonators configured to filter the radio frequency signal.

In some embodiments, the techniques described herein relate to a multiplexer for filtering radio frequency signals, the multiplexer including: a first filter including the bulk acoustic wave device; and a second filter coupled to the first filter at a common node.

In some embodiments, the techniques described herein relate to a radio frequency module including: a filter including the bulk acoustic wave device; radio frequency circuitry; and a package structure enclosing the filter and the radio frequency circuitry.

In some embodiments, the techniques described herein relate to a radio frequency system including: an antenna; a filter including the bulk acoustic wave device; and an antenna switch configured to selectively electrically connect the antenna and a signal path that includes the filter.

In some aspects, the techniques described herein relate to a method of forming a bulk acoustic wave device having a main acoustically active region and a frame region, the method including: providing a first electrode; providing a first portion of a piezoelectric layer over the first electrode providing a dielectric layer in the frame region over the first portion of the piezoelectric layer, the dielectric layer having a lower side facing the first electrode; providing a second portion of the piezoelectric layer over the first portion of the piezoelectric layer and the dielectric layer, the lower side of the dielectric layer being spaced apart at least by 10% of a total thickness of the first and second portions of the piezoelectric layer from the first electrode; providing a second electrode over the second portion of the piezoelectric layer; and providing a frame structure positioned in the frame region, the frame structure including a raised frame structure and a recessed frame structure between the raised frame structure and the main acoustically active region.

In some embodiments, the techniques described herein relate to a method wherein the dielectric layer has an upper side opposite the lower side, the upper side is spaced apart at least by 10% of the thickness of the piezoelectric layer from the second electrode.

In some embodiments, the techniques described herein relate to a method wherein the dielectric layer is positioned within 20% to 80% of the thickness of the piezoelectric layer.

In some embodiments, the techniques described herein relate to a method wherein the dielectric layer at least partially overlaps the recessed frame structure.

In some embodiments, the techniques described herein relate to a method wherein the dielectric layer includes a silicon oxide layer.

In some embodiments, the techniques described herein relate to a method wherein the dielectric layer includes an airgap.

In some aspects, the techniques described herein relate to a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a frame structure positioned in the frame region; and a dielectric layer in the frame region, the dielectric layer positioned between the second side of the piezoelectric layer and the first electrode, the piezoelectric layer between the dielectric layer and the second side being less piezoelectric than the piezoelectric layer in the main acoustically active region.

In some embodiments, the techniques described herein relate to a bulk acoustic wave device wherein the piezoelectric layer between the dielectric layer and the second side is less piezoelectric than the piezoelectric layer between the dielectric layer and the first side.

In some embodiments, the techniques described herein relate to a bulk acoustic wave device wherein the frame structure includes a raised frame structure having an inner end and an outer end, the inner end being closer to the main acoustically active region than the outer end.

In some embodiments, the techniques described herein relate to a bulk acoustic wave device wherein the dielectric layer has an inner edge and an outer edge, a distance between the inner edge of the dielectric layer and the main acoustically active region is no greater than 600 nanometers over a distance between the inner end of the raised frame structure and the main acoustically active region.

In some embodiments, the techniques described herein relate to a bulk acoustic wave device wherein the inner end of the raised frame structure aligns with the inner edge of the dielectric layer.

In some embodiments, the techniques described herein relate to a bulk acoustic wave device wherein the frame structure further includes a recessed frame structure between the raised frame structure and the main acoustically active region, the dielectric layer at least partially overlaps the recessed frame structure.

In some embodiments, the techniques described herein relate to a bulk acoustic wave device wherein the dielectric layer includes a silicon oxide layer.

In some embodiments, the techniques described herein relate to a bulk acoustic wave device wherein the dielectric layer includes an airgap.

In some embodiments, the techniques described herein relate to a bulk acoustic wave device further including a passivation layer over the second electrode.

In some embodiments, the techniques described herein relate to a bulk acoustic wave device wherein the dielectric layer has a lower side facing the first electrode, the lower side of the dielectric layer is spaced apart at least by 10% of a thickness of the piezoelectric layer from the first electrode.

In some embodiments, the techniques described herein relate to an acoustic wave filter for filtering a radio frequency signal, the acoustic wave filter including: the bulk acoustic wave device; and a plurality of additional acoustic wave resonators, the bulk acoustic wave device and the plurality of additional acoustic wave resonators configured to filter the radio frequency signal.

In some embodiments, the techniques described herein relate to a multiplexer for filtering radio frequency signals, the multiplexer including: a first filter including the bulk acoustic wave device; and a second filter coupled to the first filter at a common node.

In some embodiments, the techniques described herein relate to a radio frequency module including: a filter including the bulk acoustic wave device; radio frequency circuitry; and a package structure enclosing the filter and the radio frequency circuitry.

In some embodiments, the techniques described herein relate to a radio frequency system including: an antenna; a filter including the bulk acoustic wave device; and an antenna switch configured to selectively electrically connect the antenna and a signal path that includes the filter.

In some aspects, the techniques described herein relate to a method of forming a bulk acoustic wave device having a main acoustically active region and a frame region, the method including: providing a first electrode; providing a first portion of a piezoelectric layer over the first electrode providing a dielectric layer in the frame region over the first portion of the piezoelectric layer, the dielectric layer having a lower side facing the first electrode; providing a second portion of the piezoelectric layer over the first portion of the piezoelectric layer and the dielectric layer, the second portion of the piezoelectric layer over the dielectric layer being less piezoelectric than the piezoelectric layer in the main acoustically active region; providing a second electrode over the second portion of the piezoelectric layer; and providing a frame structure positioned in the frame region.

In some embodiments, the techniques described herein relate to a method wherein the second portion of the piezoelectric layer in the frame region is less piezoelectric than the first portion of the piezoelectric layer in the frame region.

In some embodiments, the techniques described herein relate to a method wherein the frame structure includes a raised frame structure having an inner end and an outer end, the inner end being closer to the main acoustically active region than the outer end.

In some embodiments, the techniques described herein relate to a method wherein the frame structure further includes a recessed frame structure between the raised frame structure and the main acoustically active region, the dielectric layer at least partially overlaps the recessed frame structure.

In some embodiments, the techniques described herein relate to a method wherein the dielectric layer includes a silicon oxide layer.

In some embodiments, the techniques described herein relate to a method wherein the dielectric layer includes an airgap.

In some aspects, the techniques described herein relate to a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a raised frame structure positioned in the frame region, the raised frame structure having an inner end and an outer end, the inner end being closer to the main acoustically active region than the outer end; and an airgap in the frame region, the airgap positioned between the first side and second side of the piezoelectric layer.

In some embodiments, the techniques described herein relate to a bulk acoustic wave device wherein the airgap has an inner edge and an outer edge, a distance between the inner end of the raised frame structure and the main acoustically active region being equal to or greater than a distance between the inner edge of the airgap and the main acoustically active region.

In some embodiments, the techniques described herein relate to a bulk acoustic wave device further including a recessed frame structure between the raised frame structure and the main acoustically active region.

In some embodiments, the techniques described herein relate to a bulk acoustic wave device wherein the airgap at least partially overlaps the recessed frame structure.

In some embodiments, the techniques described herein relate to a bulk acoustic wave device wherein the airgap has a lower side facing the first electrode, the lower side of the airgap is spaced apart at least by 10% of a thickness of the piezoelectric layer from the first electrode.

In some embodiments, the techniques described herein relate to a bulk acoustic wave device wherein the airgap has an upper side opposite the lower side, the upper side is spaced apart at least by 10% of the thickness of the piezoelectric layer from the second electrode.

In some embodiments, the techniques described herein relate to a bulk acoustic wave device wherein the airgap is positioned within 20% to 80% of the thickness of the piezoelectric layer.

In some embodiments, the techniques described herein relate to a bulk acoustic wave device wherein the piezoelectric layer between the airgap and the second side is less piezoelectric than the piezoelectric layer in the main acoustically active region.

In some embodiments, the techniques described herein relate to a bulk acoustic wave device further including a passivation layer over the second electrode.

In some embodiments, the techniques described herein relate to an acoustic wave filter for filtering a radio frequency signal, the acoustic wave filter including: the bulk acoustic wave device; and a plurality of additional acoustic wave resonators, the bulk acoustic wave device and the plurality of additional acoustic wave resonators configured to filter the radio frequency signal.

In some embodiments, the techniques described herein relate to a multiplexer for filtering radio frequency signals, the multiplexer including: a first filter including the bulk acoustic wave device; and a second filter coupled to the first filter at a common node.

In some embodiments, the techniques described herein relate to a radio frequency module including: a filter including the bulk acoustic wave device; radio frequency circuitry; and a package structure enclosing the filter and the radio frequency circuitry.

In some embodiments, the techniques described herein relate to a radio frequency system including: an antenna; a filter including the bulk acoustic wave device; and an antenna switch configured to selectively electrically connect the antenna and a signal path that includes the filter.

In some aspects, the techniques described herein relate to a method of forming a bulk acoustic wave device having a main acoustically active region and a frame region, the method including: providing a first electrode; providing a piezoelectric layer over the first electrode so as to include an airgap in the frame region, the piezoelectric layer having a first side facing the first electrode and a second side facing the second electrode and the airgap positioned between the first side and second side of the piezoelectric layer providing a second electrode over the piezoelectric layer; and providing a frame structure positioned in the frame region.

In some embodiments, the techniques described herein relate to a method wherein providing the piezoelectric layer includes providing a lower portion of the piezoelectric layer, providing a sacrificial layer over the lower portion of the piezoelectric layer, providing an upper portion of the piezoelectric layer over the sacrificial layer and the lower portion of the piezoelectric layer, and removing the sacrificial layer.

In some embodiments, the techniques described herein relate to a method wherein the airgap has an inner edge and an outer edge and the frame structure having an inner end and an outer end, a distance between the inner end of the frame structure and the main acoustically active region being equal to or greater than a distance between the inner edge of the airgap and the main acoustically active region.

In some embodiments, the techniques described herein relate to a method wherein the frame structure includes a raised frame structure and a recessed frame structure between the raised frame structure and the main acoustically active region.

In some embodiments, the techniques described herein relate to a method wherein the airgap at least partially overlaps the recessed frame structure.

In some embodiments, the techniques described herein relate to a method wherein the airgap has a lower side facing the first electrode, the lower side 74 wherein the piezoelectric layer between the airgap and the second side is less piezoelectric than the piezoelectric layer in the main acoustically active region.

In some aspects, the techniques described herein relate to a bulk acoustic wave device having a main acoustically active region and a frame region, the bulk acoustic wave device including: a piezoelectric layer positioned between a first electrode and a second electrode in the main acoustically active region and the frame region, the main acoustically active region having a first side, a second side, a third side, and a fourth side in a plan view, a length of the first side being at least twice a length of the second side; a raised frame structure positioned in the frame region; and a dielectric layer in the frame region.

In some embodiments, the techniques described herein relate to a bulk acoustic wave device wherein the length of the first side is at least triple the length of the second side.

In some embodiments, the techniques described herein relate to a bulk acoustic wave device wherein the second side connects the first side and the third side, and a length of the third side is at least twice the length of the second side.

In some embodiments, the techniques described herein relate to a bulk acoustic wave device wherein the second side connects the first side and the third side, and a length of the third side is at least twice the length of the second side.

In some embodiments, the techniques described herein relate to a bulk acoustic wave device wherein the fourth side connects the first side and the third side, and a length of the first side is at least twice a length of the fourth side.

In some embodiments, the techniques described herein relate to a bulk acoustic wave device further including a recessed frame structure in the frame region between the raised frame structure and the main acoustically active region.

In some embodiments, the techniques described herein relate to a bulk acoustic wave device wherein the dielectric layer at least partially overlaps the recessed frame structure.

In some embodiments, the techniques described herein relate to a bulk acoustic wave device wherein the piezoelectric layer has a first side facing the first electrode and a second side facing the second electrode, and the dielectric layer is positioned between the first side and the second side of the piezoelectric layer.

In some embodiments, the techniques described herein relate to a bulk acoustic wave device wherein the raised frame structure has an inner end and an outer end, the inner end is positioned closer to the main acoustically active region than the outer end.

In some embodiments, the techniques described herein relate to a bulk acoustic wave device wherein the dielectric layer has an inner edge and an outer edge, and a distance between the inner end of the raised frame structure and the main acoustically active region is equal to or greater than a distance between the inner edge of the dielectric layer and the main acoustically active region.

In some embodiments, the techniques described herein relate to an acoustic wave filter for filtering a radio frequency signal, the acoustic wave filter including: the bulk acoustic wave device; and a plurality of additional acoustic wave resonators, the bulk acoustic wave device and the plurality of additional acoustic wave resonators configured to filter the radio frequency signal.

In some embodiments, the techniques described herein relate to a multiplexer for filtering radio frequency signals, the multiplexer including: a first filter including the bulk acoustic wave device; and a second filter coupled to the first filter at a common node.

In some embodiments, the techniques described herein relate to a radio frequency module including: a filter including the bulk acoustic wave device; radio frequency circuitry; and a package structure enclosing the filter and the radio frequency circuitry.

In some embodiments, the techniques described herein relate to a radio frequency system including: an antenna; a filter including the bulk acoustic wave device; and an antenna switch configured to selectively electrically connect the antenna and a signal path that includes the filter.

In some aspects, the techniques described herein relate to a method of forming a bulk acoustic wave device having a main acoustically active region and a frame region, the method including: providing a piezoelectric layer positioned between a first electrode and a second electrode in the main acoustically active region and the frame region, the main acoustically active region having a first side, a second side, a third side, and a fourth side in a plan view, a length of the first side being at least twice a length of the second side; providing a raised frame structure positioned in the frame region; and providing a dielectric layer in the frame region.

In some embodiments, the techniques described herein relate to a method wherein the length of the first side is at least triple the length of the second side.

In some embodiments, the techniques described herein relate to a method wherein the second side connects the first side and the third side, and a length of the third side is at least twice the length of the second side.

In some embodiments, the techniques described herein relate to a method wherein the second side connects the first side and the third side, and a length of the third side is at least twice the length of the second side.

In some embodiments, the techniques described herein relate to a method wherein the fourth side connects the first side and the third side, and a length of the first side is at least twice a length of the fourth side.

In some embodiments, the techniques described herein relate to a method further including a recessed frame structure in the frame region between the raised frame structure and the main acoustically active region.

### BRIEF DESCRIPTION OF THE DRAWINGS

Embodiments of this disclosure will now be described, by way of non-limiting example, with reference to the accompanying drawings.

FIG. 1A is a cross-sectional diagram of a bulk acoustic wave (BAW) device including a piezoelectric layer and a dielectric layer according to an embodiment.

FIG. 1B is an enlarged view of a portion of FIG. 1A.

FIG. 1C illustrates the BAW device with a pentagon shape with curved sides in plan view.

FIG. 1D illustrates a BAW device having another shape in plan view.

FIG. 2 is a cross-sectional diagram of a BAW device including a piezoelectric layer and a dielectric layer according to an embodiment.

FIG. 3 is a graph showing dispersion curves of four different bulk acoustic wave (BAW) resonators having different stacks.

FIG. 4A is a schematic cross-sectional side view of a portion of a BAW device having a metal raised frame and an oxide raised frame.

FIG. 4B is a spurious intensity map showing the spurious intensity below fd of the BAW device of FIG. 4A.

FIG. 4C is a quality factor map showing the quality factor (Qp) of the BAW device of FIG. 4A.

FIG. 5A is a schematic cross-sectional side view of a portion of a BAW device including a piezoelectric layer and a dielectric layer according to an embodiment.

FIGS. 5B to 7C are simulated performance results of the BAW device of FIG. 5A with various parameters.

FIGS. 8A to 11G are simulated performance results of the BAW device of FIG. 1A with various parameters.

FIG. 12A is a schematic diagram of a ladder filter that includes one or more BAW resonators according to an embodiment.

FIG. 12B is a schematic diagram of a band pass filter.

FIGS. 13A, 13B, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by including a dielectric layer at least partially overlapping a frame structure.

BAW devices can include frame structures, such as raised frame structures and/or recessed frame structures. A raised frame structure can reduce lateral energy leakage from a main acoustically active region of a BAW device. A combination of a recessed frame structure and the raised frame structure may further reduce the lateral energy leakage in some applications. The raised frame structure can create a resonance at a frequency that is below a resonant frequency of the main acoustically active region of the BAW device. This resonance can be below a main resonant frequency of the BAW device. A resonance associated with the raised frame structure can be referred to as a frame mode, and more specifically a raised frame mode. The raised frame mode can be undesirable in certain applications.

This disclosure provides technical solutions that can suppress and/or eliminate raised frame modes. At the same time, technical solutions disclosed herein can maintain a desired electromechanical coupling coefficient (kt²) and significantly increase the quality factor (Q) of a BAW device. BAW devices disclosed herein can achieve significant performance improvements over other BAW devices. Filters that include BAW devices disclosed herein can provide improved performance in a variety of applications, such as but not limited to fifth generation (5G) New Radio (NR) applications. BAW devices disclosed herein can improve performance in applications where a plurality of filters are connected together with each other.

Aspects of this disclosure relate to a BAW device that includes a dielectric layer in a frame region. The dielectric layer can have a lower magnitude piezoelectric coefficient than a piezoelectric layer. The piezoelectric coefficient can be a piezoelectric coupling coefficient (e₃₃), for example. The frame region can be a peripheral region of the BAW device that surrounds the piezoelectric layer in the main acoustically active region of the BAW device. The BAW device can include a frame structure in the peripheral region. The frame structure can include one or more raised frame structures and/or one or more recessed frame structures. The peripheral region can extend beyond the frame structure toward a main acoustically active region and/or away from the main acoustically active region. By including a dielectric layer, which has a reduced piezoelectric region that is less piezoelectric than the piezoelectric layer, in the peripheral region of the BAW device, there can be less resonance associated with the frame structure than without the dielectric layer.

The dielectric layer disclosed herein can have a piezoelectric coupling coefficient (e₃₃) with a magnitude that is in a range from 0% to less than 50% of the piezoelectric coupling coefficient of the piezoelectric layer in the main acoustically active region. In certain embodiments, the e₃₃ has a magnitude in the dielectric layer that is 20% or less of a magnitude in the piezoelectric layer. The lower magnitude of the piezoelectric coupling coefficient in the dielectric layer can increase Q of the BAW device and/or attenuate one or more spurs, such a spurious associated with one or more frame modes.

BAW devices disclosed herein can significantly attenuate one or more spurious modes and increase Q, while maintaining an electromechanical coupling coefficient (kt²) at a relatively stable level. This can effectively decouple Q, kt², and strength of spurious modes in BAW devices.

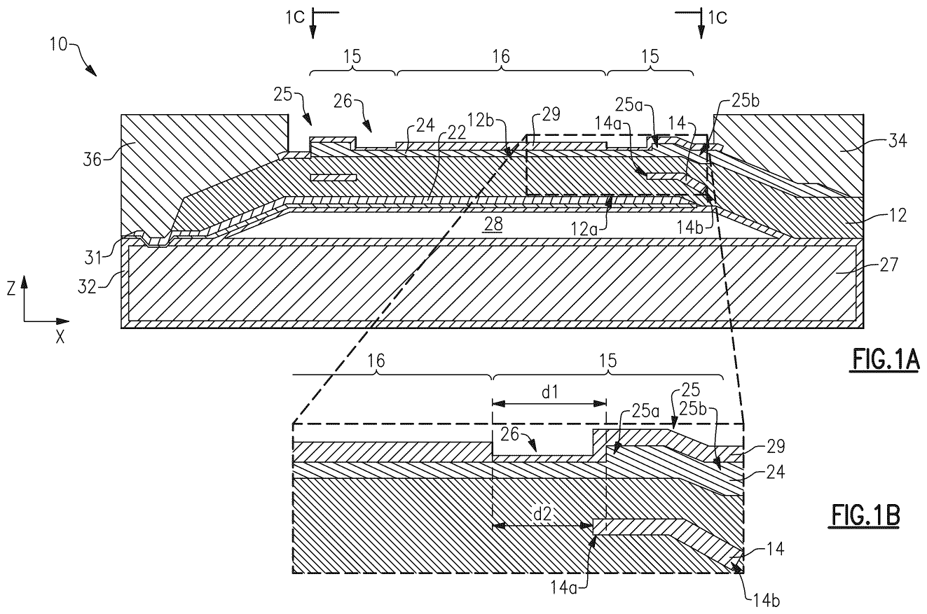

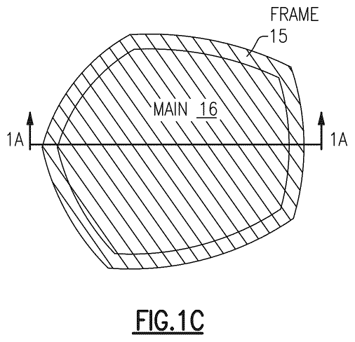

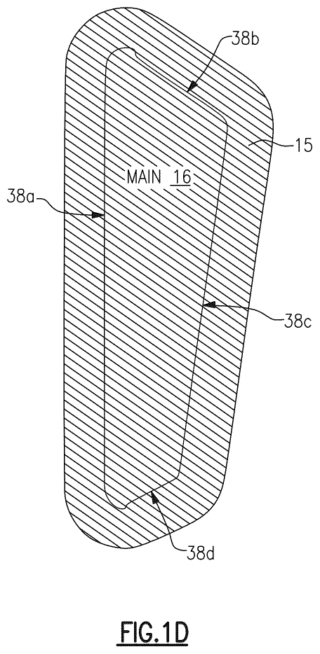

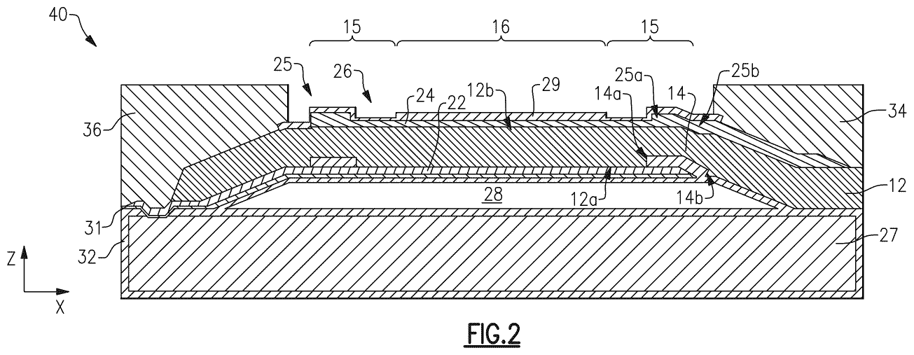

FIG. 1A is a schematic cross-sectional diagram of a BAW device 10 including a piezoelectric layer 12 and a dielectric layer 14 according to an embodiment. FIG. 1B is an enlarged view of a portion of FIG. 1A. In the BAW device 10, the dielectric layer 14 is in a frame region 15 of the BAW device 10. The piezoelectric layer 12 includes a portion in a main acoustically active region 16 and a portion in the frame region 15. The frame region 15 can at least partially surround the main acoustically active region 16 in plan view.

As illustrated, the BAW device 10 includes a first electrode 22, a second electrode 24, the piezoelectric layer 12 having a first side 12a facing the first electrode 22 and a second side 12b facing the second electrode 24, the dielectric layer 14 between the first side 12a and the second side 12b, a raised frame structure 25, a recessed frame structure 26, a support substrate 27, an acoustic reflector such as an air cavity 28, and a passivation layer 29. The BAW device 10 also includes a seed layer 31 positioned between the first electrode 22 and passivation layer 32. One or more features of the BAW device 10 may be omitted in some embodiments. The dielectric layer 14 can be symmetric or asymmetric about the main acoustically active region 16.

The dielectric layer 14 can cause the BAW device 10 to exhibit less bulk piezoelectric effect in the portion of the piezoelectric layer 12 that is in the frame region 15 of the BAW device 10. This can advantageously suppress a frame mode associated with, for example, the raised frame structure 25. The dielectric layer 14 can include any suitable dielectric material. For example, the dielectric layer 14 can include silicon-based dielectric material, such as silicon oxide (e.g., silicon dioxide (SiO₂)), silicon nitride (e.g., trisilicon tetranitride (Si₃N₄)), or silicon carbide, aluminum oxide, or a gallium-based dielectric material, such as gallium oxide or gallium nitride. The dielectric layer 14 can include any suitable oxide, nitride, or carbide. In some embodiments, it can be beneficial to implement a dielectric material for the dielectric layer 14 so as to have a relatively large acoustic impedance mismatch between the dielectric layer 14 and the piezoelectric layer 12, as such property can provide low dielectric and acoustic losses which may reduce and/or minimize the Q degradation as compared to implementing a dielectric material for the dielectric layer 14 that has a similar acoustic impedance as the piezoelectric layer 12. For example, the dielectric layer 14 can include a material that has an acoustic impedance similar to air (e.g., 428 rayl (Ry) at 0° C.) up to an acoustic impedance similar to the piezoelectric layer 12. As another example, the dielectric layer 14 can include a dielectric material that has larger acoustic impedance than the piezoelectric layer 12. In some embodiments, a difference between the acoustic impedance of the dielectric layer 12 and the acoustic impedance of the piezoelectric layer 12 can be more than 10%, more than 20%, or more than 30%. These acoustic impedance differences can be differences in magnitude. The dielectric layer 14 can have a thermal conductivity that is higher than a thermal conductivity of the piezoelectric layer 12. In some embodiments, a seed layer (not shown) can be provided over the first electrode 22 in the frame region 15 to facilitate deposition of the dielectric layer 14. Although the dielectric layer 14 may be shown as being a physical layer, the dielectric layer 14 can include an air gap.

In the BAW device 10, the piezoelectric layer 12 can extend over the air cavity 28 and the dielectric layer 14 can be positioned in the piezoelectric layer 12 in the frame region 15. The dielectric layer 14 can be less piezoelectric than the piezoelectric layer 12. The dielectric layer 14 is positioned in the frame region 15 such that the piezoelectric layer 12 in the main acoustically active region 16 has a greater magnitude piezoelectric coefficient than the frame region 15. The piezoelectric coefficient can be a piezoelectric coupling coefficient (e₃₃). In certain applications, the magnitude of e₃₃ of the dielectric layer 14 in the frame region 15 can be no more than 50% of the magnitude of e₃₃ of the piezoelectric layer 12 in the main acoustically active region 16. In some applications, the magnitude of e₃₃ of the dielectric layer 14 in the frame region 15 can be no more than 20% of the magnitude of e₃₃ of the piezoelectric layer 12. In some applications, the magnitude of e₃₃ of the dielectric layer 14 in the frame region 15 can be zero or close to zero. The dielectric layer 14 can also provide a lower electromechnical coupling coefficient (kt²) in the frame region 15 than in the main acoustically active region 16. The dielectric layer 14 can extend beyond the frame region 15 away from the main acoustically active region 16 of the BAW device 10. In some embodiments, the dielectric layer 14 extends beyond the frame region 15 away from the main acoustically active region 16 on opposing sides of the BAW device 10. In some other embodiments, the dielectric layer 14 can extend beyond a frame region on one side of a BAW device. The dielectric layer 14 can extend beyond where the first electrode 22 overlaps with the second electrode 24.

The piezoelectric layer 12 and the dielectric layer 14 can be provided in any suitable manner. In some applications, the piezoelectric layer 12 can be formed in a plurality of processes. For example, at least a portion of the piezoelectric layer 12 can be provided before providing the dielectric layer 14, and the rest of the piezoelectric layer 12 can be provided after providing the dielectric layer 14.

In some embodiments, the piezoelectric layer 12 between the dielectric layer 14 (e.g., a silicon oxide layer or an airgap) and the second side 12b can be less piezoelectric than the piezoelectric layer 12 in the main acoustically active region 16. In some embodiments, the piezoelectric layer 12 between the dielectric layer 14 and the second side 12b can be less piezoelectric than the piezoelectric layer 12 between the dielectric layer 14 and the first side 12a. For example, the less piezoelectric portion(s) of the piezoelectric layer 12 can be provided in a different manner than the other portions of the piezoelectric layer 12. For example, the less piezoelectric portion(s) of the piezoelectric layer 12 can be deposited with lower quality than the other portions of the piezoelectric layer 12.

The BAW device 10 can include frame structure including the raised frame structure 25 and the recessed frame structure 26. The dielectric layer 14 can overlap at least with the raised frame structure 25. In some embodiments, the dielectric layer 14 can also overlap with the recessed frame structure 26. The reduced bulk piezoelectric effect in the frame region 15 as compared to the main acoustically active region 16 can suppress and/or eliminate a frame mode (e.g., a raised frame mode associated with the raised frame structure and/or a recessed frame mode associated with the recessed frame structure 26) in the BAW device 10.

The raised frame structure 25 has an inner end 25a and an outer end 25b in the frame region 15. The inner end 25a is closer to the main acoustically active region 16 than the outer end 25b. In some embodiments, a distance d1 between the main acoustically active region 16 and the inner end 25a of the raised frame structure 25 can be defined by a width of the recessed frame structure 26. The dielectric layer 14 has an inner edge 14a and an outer edge 14b. The inner edge 14a is closer to the main acoustically active region 16 than the outer edge 14b. The distance d1 between the main acoustically active region 16 and the inner end 25a of the raised frame structure 25 can be equal to or greater than a distance d2 between the main acoustically active region 16 and the inner edge 14a of the dielectric layer 14 such that the dielectric layer 14 overlaps at least the inner end 25a of the raised frame structure 25. In some embodiments, the distance d2 can be no greater than 1 micrometer over the distance d1 (d2<d1+1 μm). In some embodiments, a difference between the distance d1 and the distance d2 can be less than 1 μm, less than 600 nm, less than 500 nm, less than 400 nm, less than 300 nm, less than 200 nm, or less than 100 nm. In order to provide the benefit of frame mode suppression, it can be significant to have the distance d2 to be no greater than 600 nanometers (nm) over the distance d1, and more preferably less than the distance d1.

The piezoelectric layer 12 can include a suitable material such as, but not limited to, aluminum nitride (AlN), zinc oxide (ZnO), or lead zirconium titanate (PZT). In certain applications, the piezoelectric layer 12 can include AlN. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. In certain applications, the piezoelectric layer 12 can be AlN based layer doped with Sc. Doping the piezoelectric layer 12 can adjust the resonant frequency. Doping the first piezoelectric layer 12 can increase the electromechanical coupling coefficient (kt²) of the BAW device 10. Doping to increase the kt² can be advantageous at higher frequencies where kt² can be degraded.

In certain applications, two or more piezoelectric layers in accordance with any suitable principles and advantages disclosed herein can be stacked with each other between electrodes of a BAW device. The stacked piezoelectric layers can have c-axes oriented in opposite directions in the main acoustically active region and excite an overtone mode as a main mode of a BAW resonator.

The piezoelectric layer 12 is positioned between the first electrode 22 and the second electrode 24 along a first axis (e.g., along a z-axis in FIG. 1A). The main acoustically active region 16 can be laterally between the frame region 15 along a second axis (e.g., along an x-axis in FIG. 1A). The first axis can be orthogonal to the second axis. The dielectric layer 14 can laterally surround the main acoustically active region 16 in some applications. The dielectric layer 14 is positioned between the first and second sides 12a, 12b of the piezoelectric layer 12 or between the first electrode 22 and the second electrode 24 along the first axis in the frame region 15 of the BAW device 10.

The first electrode 22 can be referred to as a lower electrode. The first electrode 22 can have a relatively high acoustic impedance. The first electrode 22 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 22 can have a relatively high acoustic impedance. The second electrode 24 can include Mo, W, Ru, Cr, Ir, Pt, Ir/Pt, or any suitable alloy and/or combination thereof. The second electrode 24 can be formed of the same material as the first electrode 22 in certain applications. The second electrode 24 can be referred to as an upper electrode. The thickness of the first electrode 22 can be approximately the same as the thickness of the second electrode 24 in the main acoustically active region 16 of the BAW device 10.

The seed layer 31 is positioned between the first electrode 22 and the passivation layer 32. The seed layer 31 can be any suitable seed layer for depositing the first electrode 22 thereon. In some embodiments, the seed layer 31 can be omitted. The passivation layer 32 can be positioned between the air cavity 28 and the first electrode 22. The passivation layer 32 can be referred to as a lower passivation layer. The passivation layer 32 can be a silicon dioxide layer or any other suitable passivation layer, such as a layer including aluminum oxide, silicon carbide, aluminum nitride, silicon nitride, silicon oxynitride, or the like.

The piezoelectric layer 12 and the electrodes 22 and 24 are positioned over a support substrate 27. The support substrate 27 can be a semiconductor substrate. The support substrate 27 can be a silicon substrate. The support substrate 27 can be any other suitable support substrate, such as quartz, silicon carbide, sapphire, glass, or any suitable ceramic (e.g., spinel, alumina, etc.).

As illustrated in FIG. 1A, the air cavity 28 can be located above the support substrate 27. The air cavity 28 is an example of an acoustic reflector. The air cavity 28 is positioned between the support substrate 27 and the first electrode 22. The dielectric layer 14 in the frame region 15 is positioned over the air cavity 28 in FIG. 1A. In the BAW device 10, the entire dielectric layer 14 can be positioned over the air cavity 28. In some applications, an air cavity can be etched into a support substrate. In certain applications, a solid acoustic mirror with alternating high acoustic impedance and low acoustic impedance layers can be included in place of an air cavity. A BAW device with an air cavity can be referred to as a film bulk acoustic wave resonator (FBAR). A BAW device with a solid acoustic mirror can be referred to as a BAW solidly mounted resonator (SMR).

The passivation layer 29 is positioned over the second electrode 24. The passivation layer 29 can be referred to as an upper passivation layer. The passivation layer 29 can be a silicon dioxide layer or any other suitable passivation layer, such as a layer including aluminum oxide, silicon carbide, aluminum nitride, silicon nitride, silicon oxynitride, or the like. In certain applications, the passivation layer 29 and the passivation layer 32 can be the same material. The passivation layer 29 can have different thicknesses in different regions of the BAW device 10. Part of the passivation layer 29 where the passivation layer 29 is thinner can form at least part of the recessed frame structure 26. In some embodiments, the passivation layer 29 can also function as a frequency trimming layer.

In the main acoustically active region 16, the piezoelectric layer 12 overlaps with the air cavity 28 and is between the first electrode 22 and the second electrode 24. Voltage is applied on opposing sides of the piezoelectric layer 12 in the main acoustically active region 16 to generate a bulk acoustic wave in the piezoelectric layer 12. The main acoustically active region 16 can provide a main mode of the BAW device 10. The main acoustically active region 16 can be the central part of the active region that is free from frame structures, such as the recessed frame structure 26 and the raised frame structure 25. The frame region 15 includes the raised frame structure 25 and the recessed frame structure 26.

While the BAW device 10 includes the raised frame structure 25 and recessed frame structure 26, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more conductive layers 34 and 36 can connect an electrode of the BAW device 10 to one or more other BAW devices, one or more integrated passive devices, one or more other circuit elements, one or more signal ports, the like, or any suitable combination thereof. In the illustrated embodiment, the conductive layer 34 is electrically connected to the second electrode 24 and be referred to as a top electrode connection, and the conductive layer 36 is electrically connected to the first electrode 22 and be referred to as a bottom electrode connection.

FIG. 1C is an example plan view of the BAW device 10 of FIG. 1A. In FIG. 1C, the frame region 15 and the main acoustically active region 16 are shown. As illustrated, the main acoustically active region 16 can correspond to the majority of the area of the BAW device 10. The frame region 15 at least partially surrounds (e.g., completely surrounds) the main acoustically active region 16 in plan view. The frame region 15 includes the recessed frame structure 26 and the raised frame structure 25 of the BAW device 10 of FIG. 1A.

FIG. 1C illustrates the BAW device 10 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

FIG. 1D is another example plan view of a BAW device. The BAW device of FIG. 1D can have an irregular quadrilateral shape in plan view. The shape of the plan view shown in FIG. 1D can be implemented in any suitable BAW devices disclosed herein. In FIG. 1D, the frame region 15 and the main acoustically active region 16 are shown. The main acoustically active region 16 can have a first side 38a, a second side 38b, a third side 38c, a fourth side 38d, and rounded corners therebetween. The first side 38a can be the longest side. The first side 38a and the third side 38c can be significantly longer than the second side 38b and the fourth side 38d. For example, the first side 38a and/or the third side 38c can be more than twice or triple the length of the second side 38b or the fourth side 38d. An outer periphery of the frame region 15 can have a generally similar shape as the main acoustically active region 16.

The conductive layers 34, 36 can be spaced by a gap in a plan view. The conductive layers 34, 36 can be arranged in any suitable manner. In some embodiments, the conductive layer 34 can be formed on the second side 38b or the fourth side 38d and the conductive layer 36 can be formed on the other side of the second side 38b or the fourth side 38d. In some other embodiments, the conductive layer 34 can be formed on the first to third sides 38a, 38b, 38c, and the conductive layer 36 can be formed on the fourth side 38d. In some applications, the shape of FIG. 1D can reduce lateral mode and increase the quality factor Qs as compared to the shape of FIG. 1C.

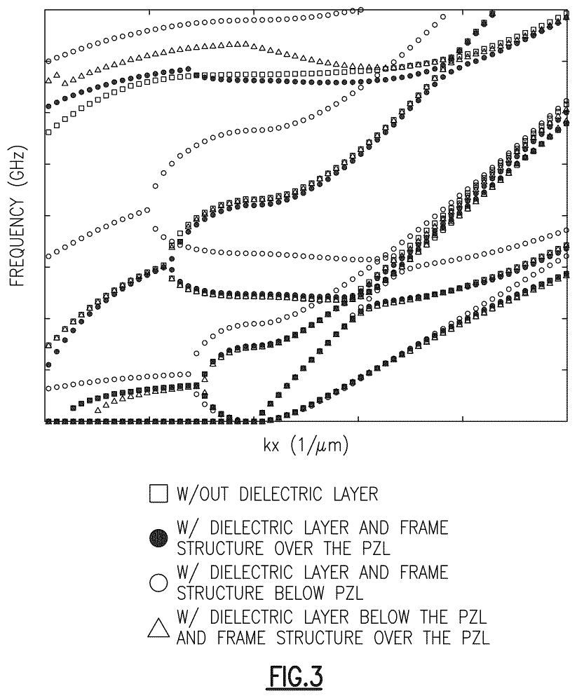

FIG. 2 is a cross-sectional diagram of a BAW device 40 including a piezoelectric layer 12 and a dielectric layer 14 according to an embodiment. The BAW device 40 is similar to the BAW device 10 of FIG. 1A, except that the dielectric layer 14 in the BAW device 40 is positioned between the piezoelectric layer 12 and the first electrode 22 in the frame region 15. The dielectric layer 14 of the piezoelectric layer 12 may not extend beyond the frame region 15 away from the main acoustically active region 16 of the BAW device 40. As illustrated, the dielectric layer 14 extends to an edge of the frame region 15 away from the main acoustically active region 16.

FIG. 3 is a graph showing dispersion curves of four different bulk acoustic wave (BAW) resonators having different stacks. One of the four BAW resonators includes no dielectric layer. Another BAW resonator includes a dielectric layer and a frame structure over the piezoelectric layer. Another BAW resonator includes a dielectric layer and a frame structure below the piezoelectric layer. Another BAW resonator includes a dielectric layer and below the piezoelectric layer and a frame structure over the piezoelectric layer. FIG. 3 indicates that the dielectric layer and the raised frame do not significantly affect the dispersion curve characteristics.

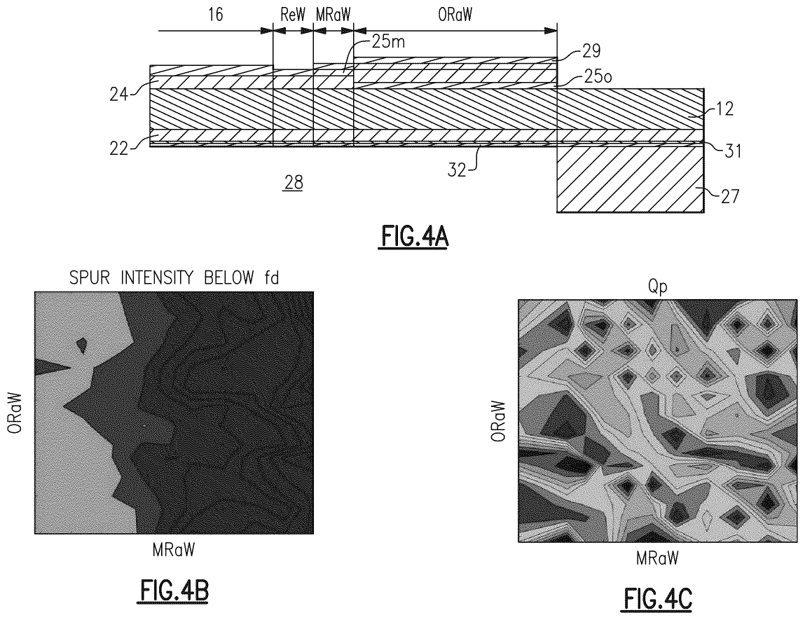

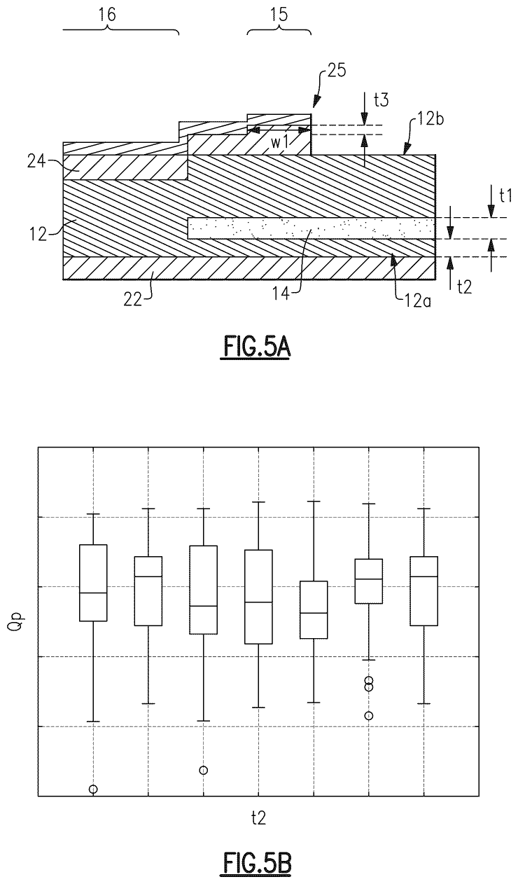

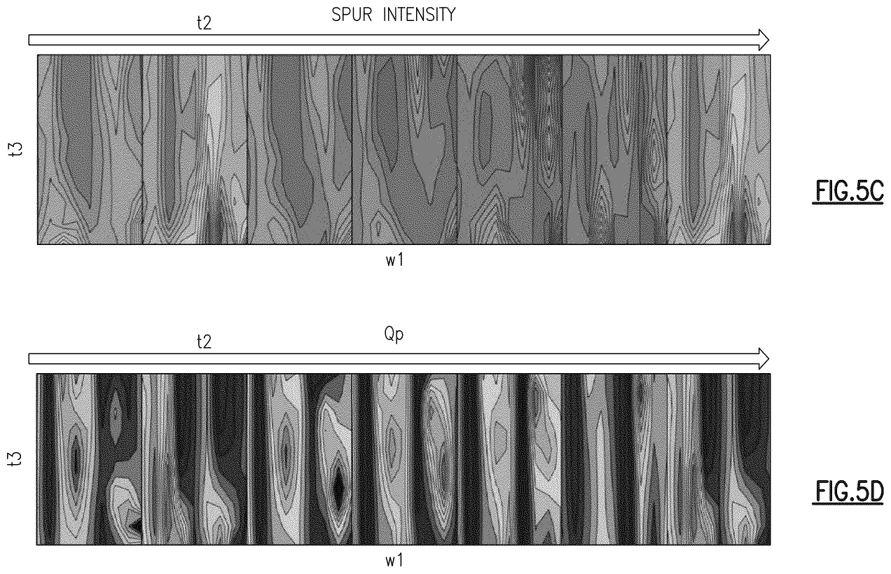

FIG. 4A is a schematic cross-sectional side view of a portion of a BAW device having a metal raised frame 25m with a width MRaW and an oxide raised frame 250 with a width ORaW. The metal raised frame 25m is spaced from the main acoustically active region 16 by a recessed frame structure 26 with a width ReW. FIG. 4B is a spurious intensity map showing the spurious intensity below fd of the BAW device of FIG. 4A at different widths MRaW, ORaW. FIG. 4C is a quality factor map showing the quality factor (Qp) of the BAW device of FIG. 4A at different widths MraW, ORaW. FIG. 4B indicates that when the metal raised frame width MRaW is greater, the BAW device creates greater spurious intensity. FIG. 4C indicates that, generally, the Qp increases from the bottom left to the top left (from small widths MRaW, ORaW to greater widths MRaW, ORaW). Therefore, it can be challenging to obtain both a relatively low spurious intensity and a relatively high Qp. Various embodiments disclosed herein can enable a BAW device to obtain a relatively low spurious intensity and a relatively high Qp.

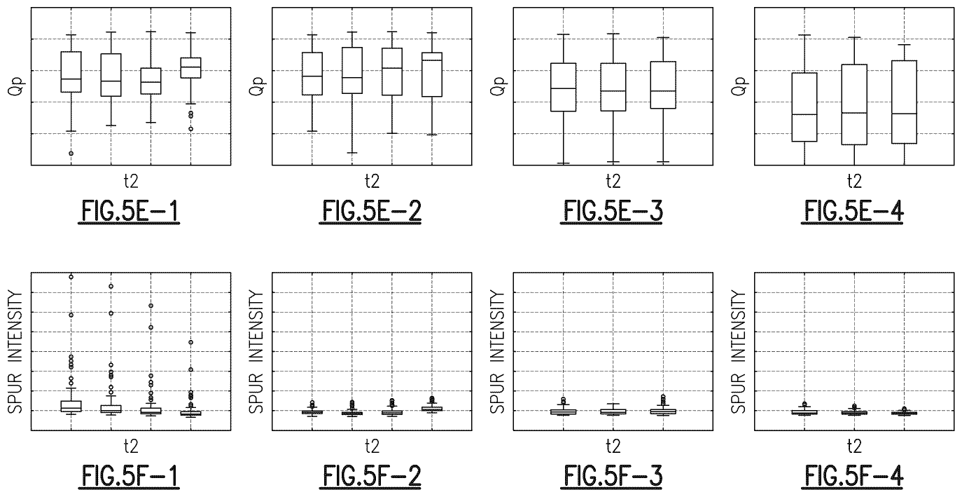

FIG. 5A is a schematic cross-sectional side view of a portion of a BAW device 42 including a piezoelectric layer 12 and a dielectric layer 14 according to an embodiment. Unless otherwise noted, the components of the BAW device 42 shown in FIG. 5A may be structurally and/or functionally the same as or generally similar to like components of other BAW devices disclosed herein. The dielectric layer 14 is positioned at least in the frame region 15. The dielectric layer 14 has a thickness t1. The dielectric layer 14 can be spaced from the first side 12a of the piezoelectric layer 12 by a portion of the piezoelectric layer 12 having a thickness t2. The BAW device 42 includes a raised frame structure 25 in the frame region 15 and has a thickness t3 and a width w1.

FIG. 5B is a graph showing simulated quality factor (Qp) ranges of the BAW device 42 of FIG. 5A at different thickness t2 of the portion of the piezoelectric layer 12 between the first side 12a and the dielectric layer 12. FIG. 5B indicates that the dielectric layer 14 does not significantly degrade the quality factor (Qp) and maintains the quality factor (Qp) at a relatively high level at any thickness t2 of the portion of the piezoelectric layer 12.

FIG. 5C is a spurious intensity map showing the spurious intensity below fd of the BAW device 42 of FIG. 5A at different width w1, thickness t2, and thickness t3. FIG. 5D is a quality factor map showing the quality factor (Qp) of the BAW device 42 of FIG. 5A at different width w1, thickness t2, and thickness t3. FIGS. 5C and 5D indicate that the presence of the dielectric layer 14 can significantly improve the spurious intensity and the quality factor (Qp).

FIG. 5E-1 is a graph showing simulated quality factor (Qp) ranges of the BAW device 42 of FIG. 5A at different thickness t2 of the portion of the piezoelectric layer 12 between the first side 12a and the dielectric layer 12 when the thickness t1 of the dielectric layer 14 has a first thickness. FIG. 5E-2 is a graph showing simulated quality factor (Qp) ranges of the BAW device 42 of FIG. 5A at different thickness t2 of the portion of the piezoelectric layer 12 between the first side 12a and the dielectric layer 12 when the thickness t1 of the dielectric layer 14 has a second thickness greater than the first thickness. FIG. 5E-3 is a graph showing simulated quality factor (Qp) ranges of the BAW device 42 of FIG. 5A at different thickness t2 of the portion of the piezoelectric layer 12 between the first side 12a and the dielectric layer 12 when the thickness t1 of the dielectric layer 14 has a third thickness greater than the second thickness. FIG. 5E-4 is a graph showing simulated quality factor (Qp) ranges of the BAW device 42 of FIG. 5A at different thickness t2 of the portion of the piezoelectric layer 12 between the first side 12a and the dielectric layer 12 when the thickness t1 of the dielectric layer 14 has a fourth thickness greater than the third thickness.

FIGS. 5E-1 to 5E-4 indicate that the vertical position of the dielectric layer 14 does not have a significant impact on the quality factor (Qp) but the thickness t1 of the dielectric layer 14 can affect the quality factor (Qp) of the BAW device 42. The quality factor (Qp) may degrade as the thickness t1 of the dielectric layer 14 increases.

FIG. 5F-1 is a graph showing simulated spurious intensity ranges of the BAW device 42 of FIG. 5A at different thickness t2 of the portion of the piezoelectric layer 12 between the first side 12a and the dielectric layer 12 when the thickness t1 of the dielectric layer 14 has a first thickness. FIG. 5F-2 is a graph showing simulated spurious intensity ranges of the BAW device 42 of FIG. 5A at different thickness t2 of the portion of the piezoelectric layer 12 between the first side 12a and the dielectric layer 12 when the thickness t1 of the dielectric layer 14 has a second thickness greater than the first thickness. FIG. 5F-3 is a graph showing simulated spurious intensity ranges of the BAW device 42 of FIG. 5A at different thickness t2 of the portion of the piezoelectric layer 12 between the first side 12a and the dielectric layer 12 when the thickness t1 of the dielectric layer 14 has a third thickness greater than the second thickness. FIG. 5F-4 is a graph showing simulated spurious intensity ranges of the BAW device 42 of FIG. 5A at different thickness t2 of the portion of the piezoelectric layer 12 between the first side 12a and the dielectric layer 12 when the thickness t1 of the dielectric layer 14 has a fourth thickness greater than the third thickness.

FIGS. 5F-1 to 5F-4 indicate that the vertical position of the dielectric layer 14 and the thickness t1 of the dielectric layer 14 do not have a significant impact on the spurious intensity of the BAW device 42. Regardless of the vertical position and the thickness t1 of the dielectric layer 14, the presence of the dielectric layer 14 can improve the spurious intensity as compared to a BAW device without the dielectric layer 14.

In some embodiments, the dielectric layer 14 can be vertically positioned in any suitable location in the piezoelectric layer 12. For example, a lower side of the dielectric layer 14 (e.g., a silicon oxide layer or an airgap) facing the first electrode 22 can be spaced from the first side 12a of the piezoelectric layer 12 (or from the first electrode 22) by 5% to 95%, 10% to 90%, 20% to 80%, 30% to 70%, 40% to 60%, 50% to 70%, or 60% to 80% of the thickness of the piezoelectric layer 12. For example, an upper side of the dielectric layer 14 (e.g., a silicon oxide layer or an airgap) facing the second electrode 24 can be spaced from the second side 12b of the piezoelectric layer 12 (or from the second electrode 24) by 5% to 95%, 10% to 90%, 20% to 80%, 30% to 70%, 40% to 60%, 50% to 70%, or 60% to 80% of the thickness of the piezoelectric layer 12. Thus, the dielectric layer 14 can be positioned in the piezoelectric layer 12 within these ranges. In the simulations of FIGS. 5B to 5F-4, the thickness of the piezoelectric layer 12 is fixed. However, in some embodiments, the total thickness of the piezoelectric layer 12 and the dielectric layer 14 can be fixed, instead, to reduce the negative effect of the quality factor (Qp) degradation due to increase of the thickness t1 of the dielectric layer 14. In such embodiments, the second side 12b of the piezoelectric layer 12 may be flat.

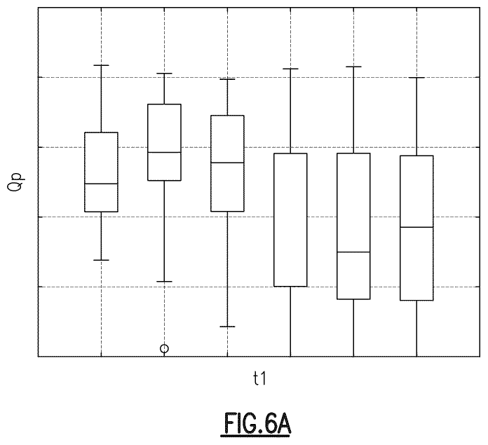

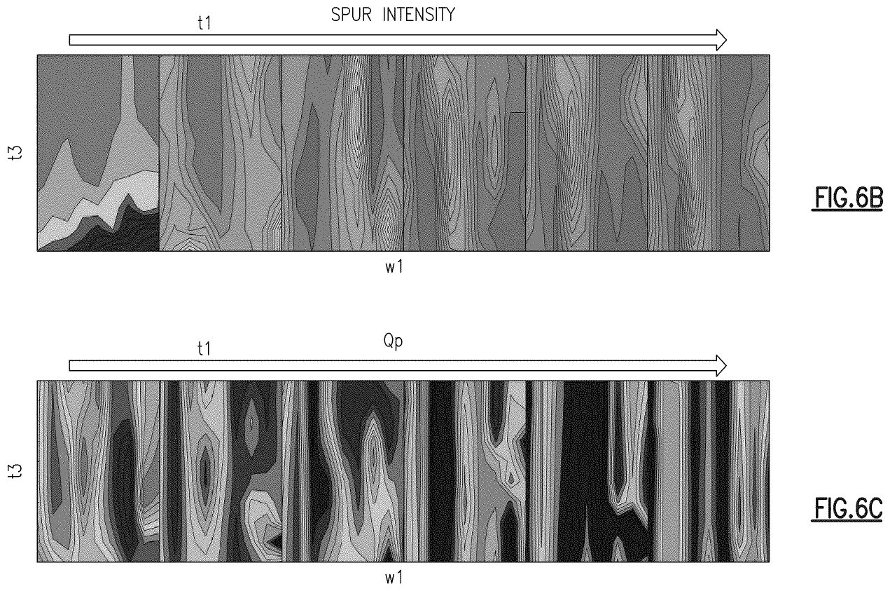

FIG. 6A is a graph showing simulated quality factor (Qp) ranges of the BAW device 42 of FIG. 5A at different thickness t1 of the dielectric layer 14 positioned between the first side 12a and the first electrode 22. FIG. 6B is a spurious intensity map showing the spurious intensity below fd of the BAW device 42 of FIG. 5A at different width w1, thickness t1, and thickness t3 when the dielectric layer 14 positioned between the first side 12a and the first electrode 22. FIG. 6C is a quality factor map showing the quality factor (Qp) of the BAW device 42 of FIG. 5A at different width w1, thickness t1, and thickness t3 when the dielectric layer 14 positioned between the first side 12a and the first electrode 22.

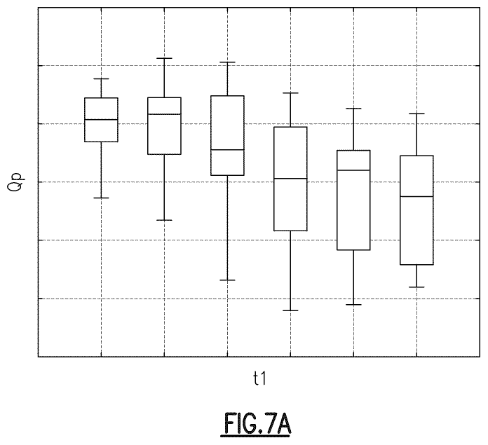

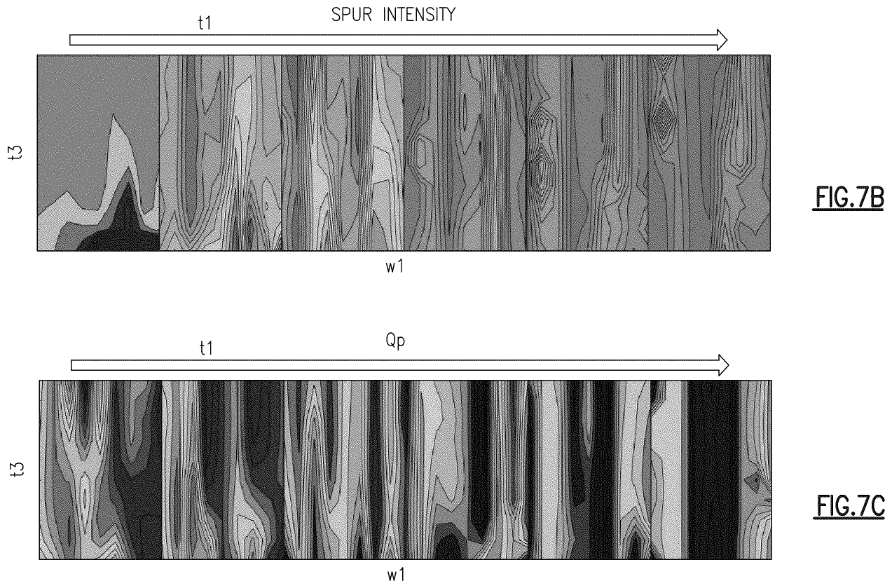

FIG. 7A is a graph showing simulated quality factor (Qp) ranges of the BAW device 42 of FIG. 5A at different thicknesses t1 of the dielectric layer 14 positioned between the second side 12b and the second electrode 24. FIG. 7B is a spurious intensity map showing the spurious intensity below fd of the BAW device 42 of FIG. 5A at different widths w1, thicknesses t1, and thicknesses t3 when the dielectric layer 14 is positioned between the second side 12b and the second electrode 24. FIG. 7C is a quality factor map showing the quality factor (Qp) of the BAW device 42 of FIG. 5A at different widths w1, thicknesses t1, and thicknesses t3 when the dielectric layer 14 is positioned between the second side 12b and the second electrode 24.

FIGS. 6A-7C indicate that the presence of the dielectric layer 14 can improve the quality factor (Qp) and the spurious intensity regardless of the vertical position of the dielectric layer 14. FIGS. 5B-7C indicate that the advantage of the dielectric layer 14 can be pronounced when the dielectric layer 14 is positioned between the first side 12a and the second side 12b of the piezoelectric layer 12.

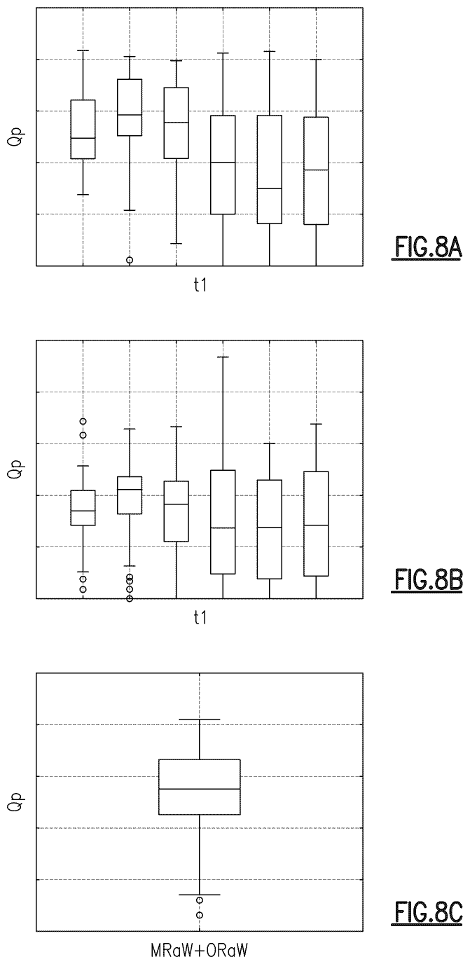

FIGS. 8A and 8B are graphs showing simulated quality factor (Qp) ranges of BAW devices according to some embodiments. FIG. 8C is a graph showing a simulated quality factor (Qp) range of a BAW device according to an embodiment. The BAW devices used in the simulations of FIGS. 8A to 8C are similar to the BAW device 10 of FIG. 1A. In the simulation of FIG. 8A, the recessed frame structure 26 is omitted and the raised frame structure 25 and the dielectric layer 14 abut the main acoustically active region 16 The raised frame structure 25 used in the simulation of FIG. 8A includes a metal raised frame and an oxide raised frame between the main acoustically active region 16 and the metal raised frame. In the simulation of FIG. 8B, the dielectric layer 14 is spaced from the main acoustically active region 16 by a width of the recessed frame structure 26. The raised frame structure 25 used in the simulation of FIG. 8B includes a metal raised frame. In the simulation of FIG. 8C, the dielectric layer 14 is spaced from the main acoustically active region 16 by a width of the recessed frame structure 26. The raised frame structure 25 used in the simulation of FIG. 8C includes a metal raised frame and an oxide raised frame between the main acoustically active region 16 and the metal raised frame.

FIGS. 8A and 8B indicate that the distance d2 between the dielectric layer 14 and the main acoustically active region 16 can affect the quality factor (Qp). It can be advantageous, in some embodiments, to position the inner edge 14a of the dielectric layer 14 to be as close to the main acoustically active region 16 as possible. For example, it can be advantageous to position the inner edge 14a of the dielectric layer 14 to be laterally between the inner end 25a of the raised frame structure 25 and the main acoustically active region 16. Also, the combination of the recessed frame structure 26 and the raised frame structure 25, especially when the raised frame structure 25 includes a metal raised frame and an oxide raised frame, can improve the quality factor (Qp).

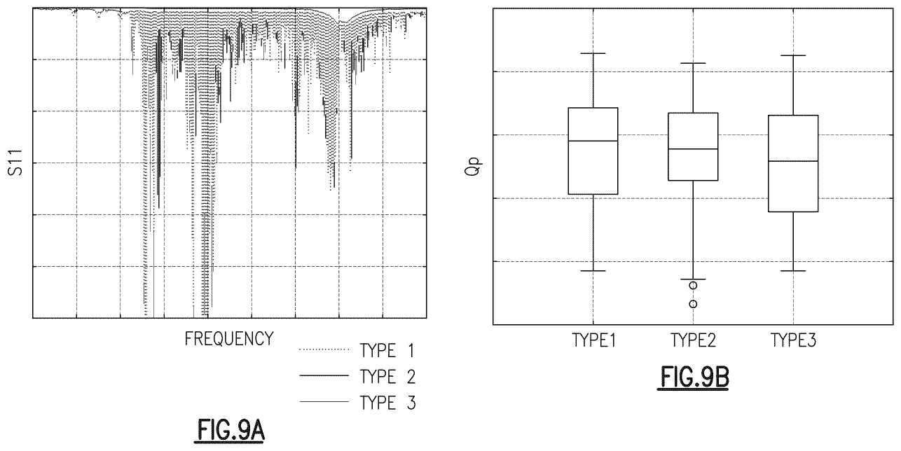

FIG. 9A is a graph showing simulated S11 parameters of three variations (Types 1-3) of the BAW device 10. FIG. 9B is a graph showing simulated quality factor (Qp) ranges of the three variations (Types 1-3) of the BAW device 10. Type 1 of the BAW device 10 used in the simulations of FIGS. 9A and 9B includes the dielectric layer 14 positioned between the second side 12b and the second electrode 24 and only below entire raised frame structure 25. Type 2 of the BAW device 10 used in the simulations of FIGS. 9A and 9B includes the dielectric layer 14 positioned between the first side 12a and the first electrode 22 and below entire raised frame structure 25 and extends outwardly away from the frame region 15. Type 3 of the BAW device 10 used in the simulations of FIGS. 9A and 9B includes the dielectric layer 14 positioned between the second side 12b and the second electrode 24 and below entire raised frame structure 25 and extends outwardly away from the frame region 15. The dielectric layer 14 of Types 1-3 includes silicon oxide layer.

FIGS. 9A and 9B indicate that the differences between Types 1 to 3 of the BAW device 10 do not significantly affect the quality factor (Qp) and below fs spurious mode characteristics. FIGS. 9A and 9B indicate that Type 2 of the BAW device 10 can have a slightly tighter quality factor (Qp) distribution than Types 1 and 3.

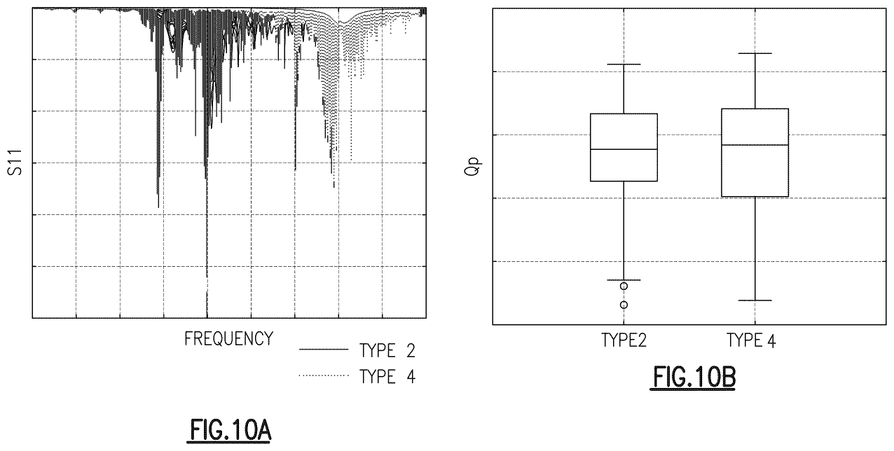

FIG. 10A is a graph showing simulated S11 parameters of two variations (Types 2 and 4) of the BAW device 10. FIG. 10B is a graph showing simulated quality factor (Qp) ranges of the two variations (Types 2 and 4) of the BAW device 10. FIG. 10C is a quality factor map showing the quality factor (Qp) of Type 2 of the BAW device 10 at different widths MraW, ORaW. FIG. 10D is a quality factor map showing the quality factor (Qp) of Type 4 of the BAW device 10 at different widths MraW, ORaW. Type 4 of the BAW device 10 used in the simulations of FIGS. 10A to 10D is similar to Type 2 except that the piezoelectric layer 12 of Type 4 has a low quality piezoelectric region over the dielectric layer 14. The low quality piezoelectric region of the piezoelectric layer 12 has a lower piezoelectricity than in other portions, such as in the main acoustically active region, of the piezoelectric layer 12.

FIGS. 10A to 10D indicate that the low quality piezoelectric region of the piezoelectric layer 12 can provide even lower strength of spurious mode while maintaining the relatively high quality factor (Qp). The low quality piezoelectric region of the piezoelectric layer 12 can be provided in any suitable BAW devices disclosed herein.

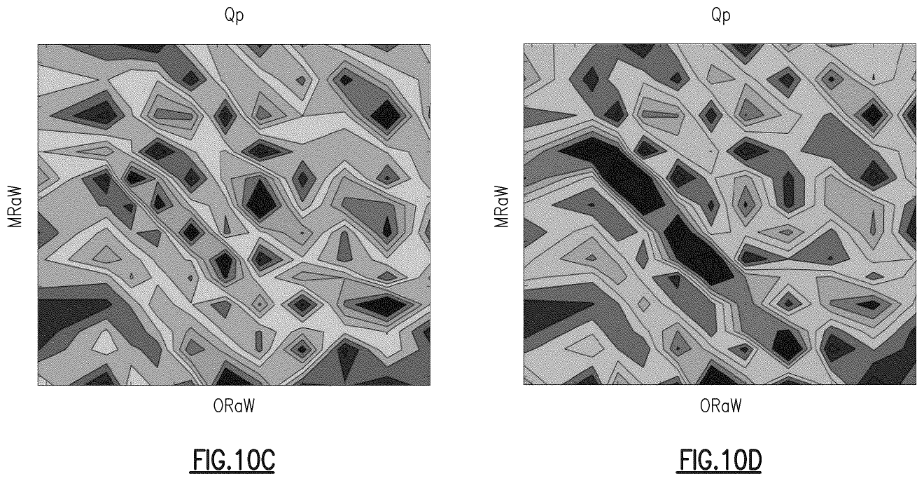

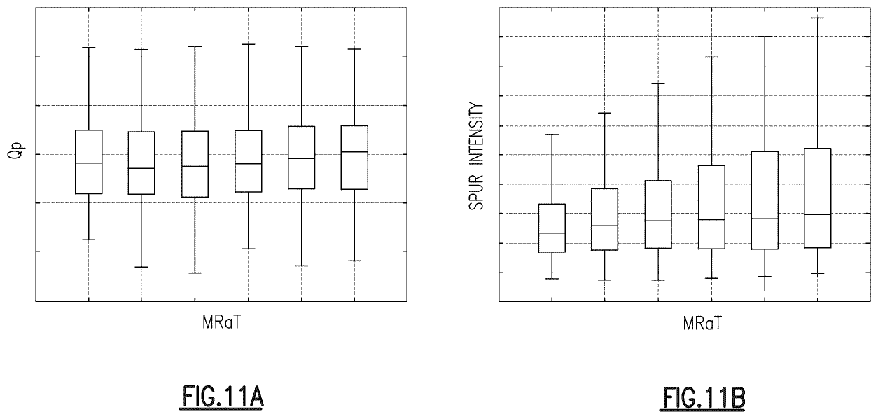

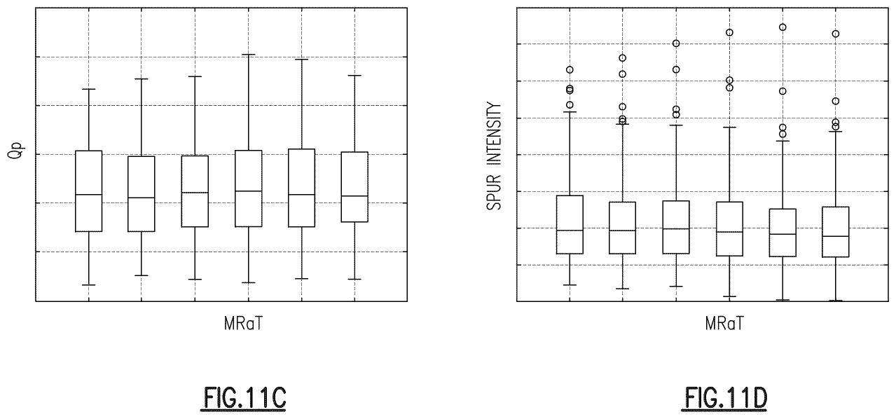

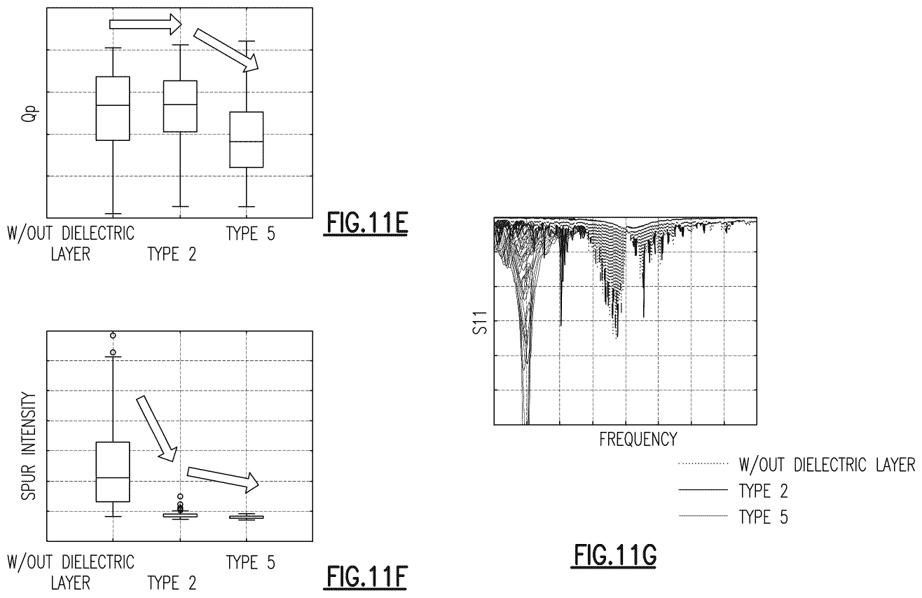

FIG. 11A is a graph showing simulated quality factor (Qp) ranges of Type 5 of the BAW device 10 at different thicknesses of the raised frame structure 25. FIG. 11B is a graph showing simulated spurious intensity ranges of Type 5 of the BAW device 10 at different thicknesses of the raised frame structure 25. FIG. 11C is a graph showing simulated quality factor (Qp) ranges of Type 6 of the BAW device 10 at different thicknesses of the raised frame structure 25. FIG. 11D is a graph showing simulated spurious intensity ranges of Type 6 of the BAW device 10 at different thicknesses of the raised frame structure 25. Type 5 of the BAW device 10 used in the simulations of FIGS. 11A and 11B is similar to Type 2 except that the dielectric layer 14 includes an airgap. Type 6 of the BAW device 10 used in the simulations of FIGS. 11A and 11B is similar to Type 1 except that the dielectric layer 14 includes an airgap.

FIGS. 11A to 11D indicate that the thickness of the raised frame structure 25 does not significantly affect the function of the dielectric layer 14 (the airgap). However, in Type 6 of the BAW device 10, the spurious intensity performance can degrade when the thickness of the raised frame structure 25 is thicker.

FIG. 11E is a graph showing simulated quality factor (Qp) ranges of three different BAW devices. FIG. 11F is a graph showing simulated spurious intensity ranges of the three different BAW devices. FIG. 11G is a graph showing simulated S11 parameters the three different BAW devices. The three different BAW devices include a BAW device without the dielectric layer 14, Type 2 of the BAW device 10, and Type 5 of the BAW device 10.

FIG. 11E indicates that the quality factor (Qp) may degrade when an airgap is used as the dielectric layer 14. FIGS. 11F and 11G indicate that the spurious intensity can be significantly lowered when the dielectric layer 14 is included in a BAW device.

Various embodiments of BAW devices disclosed herein can be formed in any suitable manner. For example, a method of forming a bulk acoustic wave device can include: providing a first electrode; providing a first portion of a piezoelectric layer over the first electrode providing a dielectric layer in the frame region over the first portion of the piezoelectric layer, the dielectric layer having an inner edge and an outer edge; providing a second portion of the piezoelectric layer over the first portion of the piezoelectric layer and the dielectric layer; providing a second electrode over the second portion of the piezoelectric layer; and providing a raised frame structure positioned in the frame region, the raised frame structure having an inner end and an outer end, the inner end being closer to the main acoustically active region than the outer end, a distance between the inner end of the raised frame structure and the main acoustically active region being equal to or greater than a distance between the inner edge of the dielectric layer and the main acoustically active region. For another example, a method of forming a bulk acoustic wave device can include: providing a first electrode; providing a first portion of a piezoelectric layer over the first electrode providing a dielectric layer in the frame region over the first portion of the piezoelectric layer, the dielectric layer having a lower side facing the first electrode; providing a second portion of the piezoelectric layer over the first portion of the piezoelectric layer and the dielectric layer, the lower side of the dielectric layer being spaced apart at least by 10% of a total thickness of the first and second portions of the piezoelectric layer from the first electrode; providing a second electrode over the second portion of the piezoelectric layer; and providing a frame structure positioned in the frame region, the frame structure including a raised frame structure and a recessed frame structure between the raised frame structure and the main acoustically active region. For another example, a method of forming a bulk acoustic wave device can include: providing a first electrode; providing a first portion of a piezoelectric layer over the first electrode providing a dielectric layer in the frame region over the first portion of the piezoelectric layer, the dielectric layer having a lower side facing the first electrode; providing a second portion of the piezoelectric layer over the first portion of the piezoelectric layer and the dielectric layer, the second portion of the piezoelectric layer over the dielectric layer being less piezoelectric than the piezoelectric layer in the main acoustically active region; providing a second electrode over the second portion of the piezoelectric layer; and providing a frame structure positioned in the frame region. For another example, a method of forming a bulk acoustic wave device can include: providing a first electrode; providing a piezoelectric layer over the first electrode so as to include an airgap in the frame region, the piezoelectric layer having a first side facing the first electrode and a second side facing the second electrode and the airgap positioned between the first side and second side of the piezoelectric layer providing a second electrode over the piezoelectric layer; and providing a frame structure positioned in the frame region. In some embodiments, providing the piezoelectric layer includes providing a lower portion of the piezoelectric layer, providing a sacrificial layer over the lower portion of the piezoelectric layer, providing an upper portion of the piezoelectric layer over the sacrificial layer and the lower portion of the piezoelectric layer, and removing the sacrificial layer.

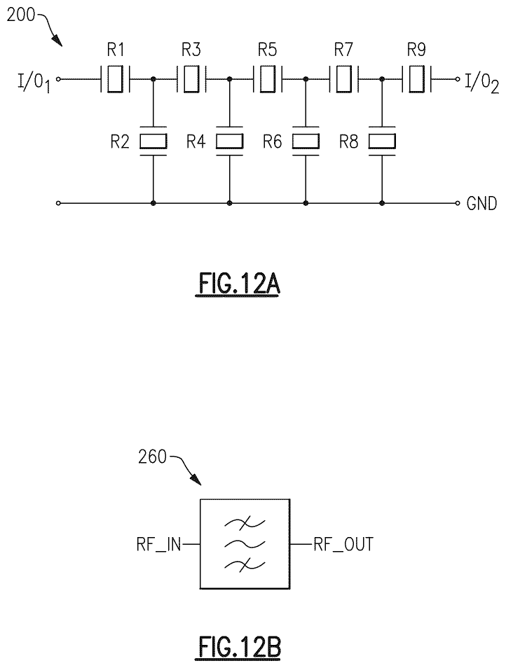

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O1 and a second input/output port I/O2. Any suitable number of series acoustic wave resonators can be included in a ladder filter. Any suitable number of shunt acoustic wave resonators can be included in a ladder filter. The first input/output port I/O1 can be a transmit port and the second input/output port I/O2 can be an antenna port. Alternatively, first input/output port I/O1 can be a receive port and the second input/output port I/O2 can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The BAW resonators disclosed herein can be advantageous for implementing BAW devices with relatively high Qp and relatively low spurious intensity. BAW resonators disclosed herein can have significantly better performance than a variety of other BAW resonators. This can be advantageous in meeting demanding specifications for acoustic wave filters, such as performance specifications for certain 5G applications.

FIG. 12B is a schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

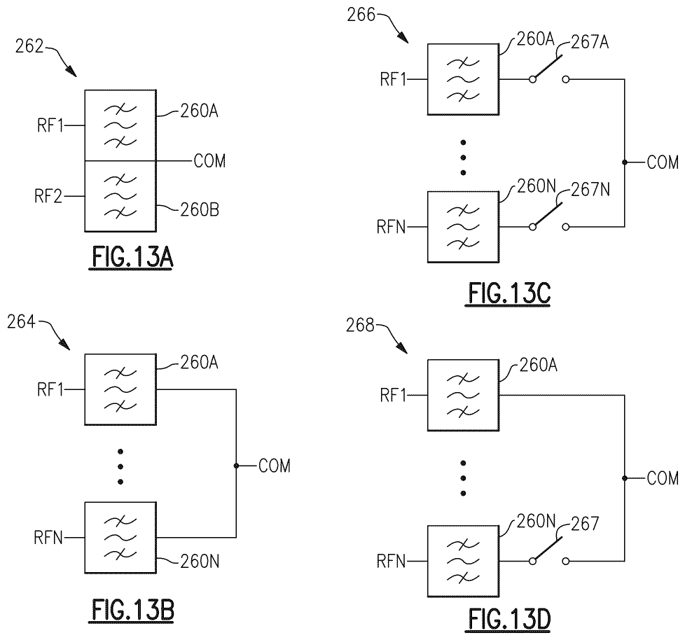

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

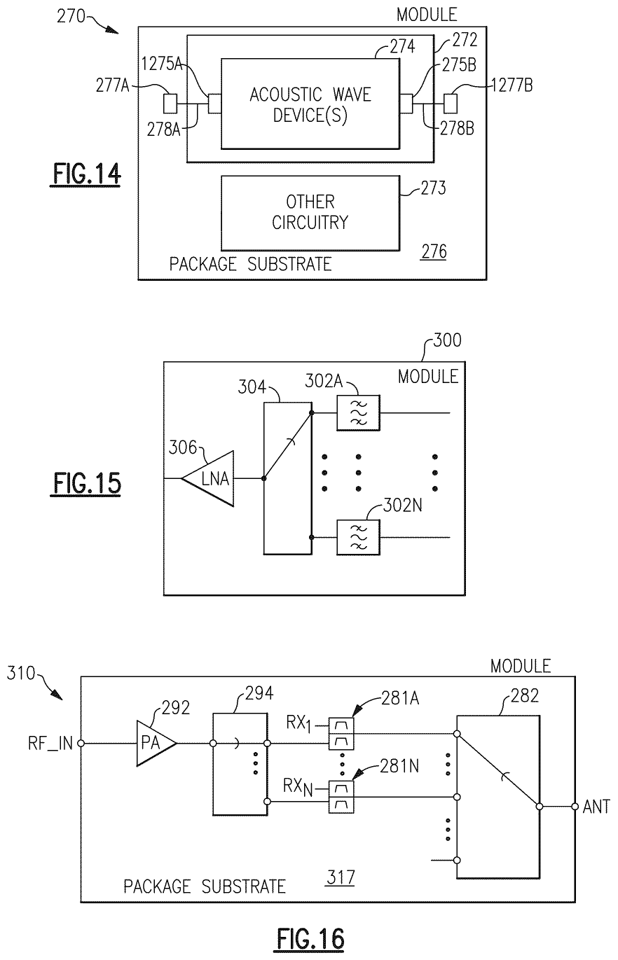

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

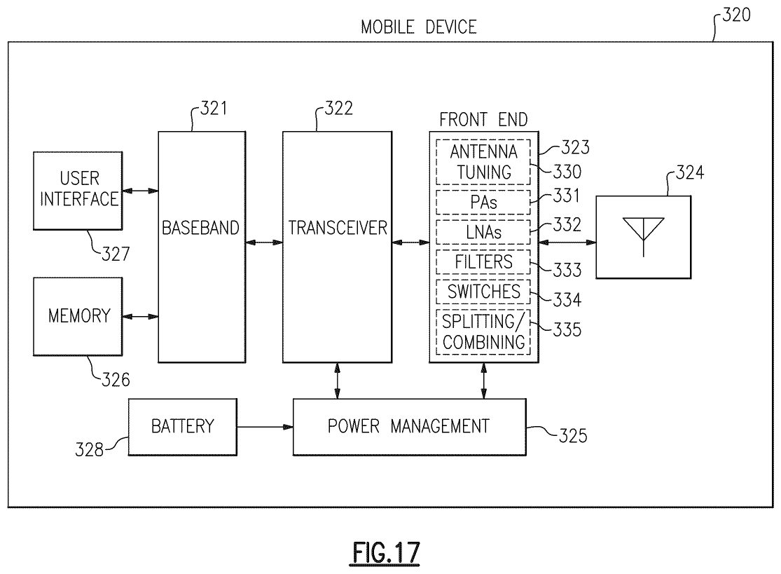

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having a main acoustically active region and a frame region, the bulk acoustic wave device comprising:
a piezoelectric layer positioned between a first electrode and a second electrode in the main acoustically active region and the frame region, the piezoelectric layer having a first side facing the first electrode and a second side facing the second electrode;
a raised frame structure positioned in the frame region, the raised frame structure having an inner end and an outer end, the inner end being closer to the main acoustically active region than the outer end; and
a dielectric layer in the frame region, the dielectric layer positioned between the first side and the second side of the piezoelectric layer, the dielectric layer having an inner edge and an outer edge, a distance between the inner end of the raised frame structure and the main acoustically active region being equal to or greater than a distance between the inner edge of the dielectric layer and the main acoustically active region so as to suppress a frame mode associated with the raised frame structure.

2. The bulk acoustic wave device of claim 1 further comprising a recessed frame structure in the frame region between the raised frame structure and the main acoustically active region.

3. The bulk acoustic wave device of claim 2 wherein the dielectric layer at least partially overlaps the recessed frame structure.

4. The bulk acoustic wave device of claim 1 wherein the inner end of the raised frame structure aligns with the inner edge of the dielectric layer.

5. The bulk acoustic wave device of claim 1 wherein the dielectric layer includes a silicon oxide layer.

6. The bulk acoustic wave device of claim 1 wherein the dielectric layer includes an airgap.

7. The bulk acoustic wave device of claim 1 wherein the dielectric layer overlaps at least an entire portion of the raised frame structure.

8. The bulk acoustic wave device of claim 1 further comprising a passivation layer over the second electrode.

9. The bulk acoustic wave device of claim 1 wherein the dielectric layer has a lower side facing the first electrode, the lower side of the dielectric layer is spaced apart at least by 10% of a thickness of the piezoelectric layer from the first electrode.

10. A multiplexer for filtering radio frequency signals, the multiplexer comprising:
a first filter including the bulk acoustic wave device of claim 1; and
a second filter coupled to the first filter at a common node.

11. A radio frequency module comprising:
a filter including the bulk acoustic wave device of claim 1;
radio frequency circuitry; and
a package structure enclosing the filter and the radio frequency circuitry.

12. A radio frequency system comprising:
an antenna;
a filter including the bulk acoustic wave device of claim 1; and
an antenna switch configured to selectively electrically connect the antenna and a signal path that includes the filter.

13. A method of forming a bulk acoustic wave device having a main acoustically active region and a frame region, the method comprising:
providing a first electrode;
providing a first portion of a piezoelectric layer over the first electrode;
providing a dielectric layer in the frame region over the first portion of the piezoelectric layer, the dielectric layer having an inner edge and an outer edge;
providing a second portion of the piezoelectric layer over the first portion of the piezoelectric layer and the dielectric layer;
providing a second electrode over the second portion of the piezoelectric layer; and
providing a raised frame structure positioned in the frame region, the raised frame structure having an inner end and an outer end, the inner end being closer to the main acoustically active region than the outer end, a distance between the inner end of the raised frame structure and the main acoustically active region being equal to or greater than a distance between the inner edge of the dielectric layer and the main acoustically active region.

14. The method of claim 13 further comprising providing a recessed frame structure in the frame region between the raised frame structure and the main acoustically active region.

15. The method of claim 13 wherein the dielectric layer includes a silicon oxide layer.

16. The method of claim 13 wherein the dielectric layer includes an airgap.

17. The method of claim 13 wherein the dielectric layer overlaps at least an entire portion of the raised frame structure.

18. The method of claim 13 further comprising a passivation layer over the second electrode.

19. The method of claim 13 wherein the dielectric layer has a lower side facing the first electrode, the lower side of the dielectric layer is spaced apart at least by 10% of a thickness of the piezoelectric layer from the first electrode.

20. An acoustic wave filter for filtering a radio frequency signal, the acoustic wave filter comprising:
a bulk acoustic wave device having a main acoustically active region and a frame region, the bulk acoustic wave device including: a piezoelectric layer positioned between a first electrode and a second electrode in the main acoustically active region and the frame region, the piezoelectric layer having a first side facing the first electrode and a second side facing the second electrode; a raised frame structure positioned in the frame region, the raised frame structure having an inner end and an outer end, the inner end being closer to the main acoustically active region than the outer end; and a dielectric layer in the frame region, the dielectric layer positioned between the first side and the second side of the piezoelectric layer, the dielectric layer having an inner edge and an outer edge, a distance between the inner end of the raised frame structure and the main acoustically active region being equal to or greater than a distance between the inner edge of the dielectric layer and the main acoustically active region; and
a plurality of additional acoustic wave resonators, the bulk acoustic wave device and the plurality of additional acoustic wave resonators configured to filter the radio frequency signal.
